(19) United States
(12) Patent Application Publication
(10) Pub. No.: US 2011/0210389 A1
(43) Pub. Date: Sep. 1, 2011

(54) Transistor Comprising a Buried High-K Metal Gate Electrode Structure

(75) Inventors: Uwe Griebenow, Markleeberg (DE); Jan Hoentschel, Dresden (DE); Thilo Scheiper, Dresden (DE); Sven Beyer, Dresden (DE)

(73) Assignee: GLOBALFOUNDRIES Inc., Grand Cayman (KY)

(21) Appl. No.: 13/006,048

(22) Filed: Jan. 13, 2011

(30) Foreign Application Priority Data
Feb. 26, 2010 (DE) 10 2010 002 412.0

(51) Int. Cl. H01L 29/78; H01L 21/336

(52) U.S. Cl. 257/330; 438/270; 257/E21.41; 257/E29.262

(57) ABSTRACT

A buried gate electrode structures may be formed in the active regions of sophisticated transistors by providing a recess in the active region and incorporating appropriate gate materials, such as a high-k dielectric material and a metal-containing electrode material. Due to the recessed configuration, the channel length and thus the channel controllability may be increased, without increasing the overall lateral dimensions of the transistor structure.

### BACKGROUND OF THE INVENTION

1. Field of the Invention

Generally, the present disclosure relates to the fabrication of highly sophisticated integrated circuits including transistor elements having a non-planar channel architecture.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout, wherein field effect transistors represent one important type of circuit element that substantially determines performance of the integrated circuits. Generally, a plurality of process technologies are currently practiced, wherein, for many types of complex circuitry, including field effect transistors, MOS technology is currently one of the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer. A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed adjacent to the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on the dopant concentration, the mobility of the charge carriers and, for a planar transistor architecture. on the distance between the source and drain regions, which is also referred to as channel length.

Presently, the vast majority of integrated circuits are formed on the basis of silicon due to its substantially unlimited availability, the well-understood characteristics of silicon and related materials and processes and the experience gathered during the past 50 years. Therefore, silicon will likely remain the material of choice for future circuit generations designed for mass products. One reason for the importance of silicon in fabricating semiconductor devices has been the superior characteristics of a silicon/silicon dioxide interface that allows reliable electrical insulation of different regions from each other. The silicon/silicon dioxide interface is stable at high temperatures and, thus, allows the performance of subsequent high temperature processes, as are required, for example, for anneal cycles to activate dopants and to cure crystal damage without sacrificing the electrical characteristics of the interface.

For the reasons pointed out above, in field effect transistors, silicon dioxide is preferably used as a base material for gate insulation layers that separate the gate electrode, frequently comprised of polysilicon or other metal-containing materials, from the silicon channel region. In steadily improving device performance of field effect transistors, the length of the channel region has been continuously decreased to improve switching speed and drive current capability. Since the transistor performance is controlled by, among other things, the voltage supplied to the gate electrode to invert the surface of the channel region to a sufficiently high charge density for providing the desired drive current for a given supply voltage, a certain degree of capacitive coupling, provided by the capacitor formed by the gate electrode, the channel region and the silicon dioxide disposed therebetween, has to be maintained. It turns out that decreasing the channel length for a planar transistor configuration requires an increased capacitive coupling to avoid the so-called short channel behavior during transistor operation. The short channel behavior may lead to an increased leakage current and to a pronounced dependence of the threshold voltage on the channel length. Aggressively scaled planar transistor devices with a relatively low supply voltage and thus reduced threshold voltage may suffer from an exponential increase of the leakage current due to the required enhanced capacitive coupling of the gate electrode to the channel region. Thus, the thickness of the silicon dioxide layer has to be correspondingly decreased to provide the required capacitance between the gate and the channel region. For example, a channel length of approximately 0.08 μm may require a gate dielectric made of silicon dioxide as thin as approximately 1.2 nm. Although usage of high speed transistor elements having an extremely short channel may typically be restricted to high speed applications, whereas transistor elements with a longer channel may be used for less critical applications, such as storage transistor elements, the relatively high leakage current caused by direct tunneling of charge carriers through an ultra-thin silicon dioxide gate insulation layer may reach values for an oxide thickness in the range of 1-2 nm that may no longer be compatible with requirements for many types of circuits.

For these reasons, a plurality of alternative approaches have been developed in an attempt to further enhance performance of planar transistors, while avoiding or reducing the above-described problems. For instance, replacing silicon dioxide as a base material for gate insulation layers has been considered, in particular for extremely thin silicon dioxide based gate layers of sophisticated transistor elements. For example, dielectric materials with significantly increased dielectric constants of 10.0 and higher, also referred to as high-k dielectric materials, such as hafnium oxide based materials, zirconium based materials and the like, may be used in gate electrode structures of advanced transistors, thereby providing a high capacitive coupling with an acceptable physical thickness of the gate dielectric material. To this end, several approaches have been developed in which a high-k dielectric material, possibly in combination with a very thin conventional dielectric material, are provided as gate dielectric materials in combination with a metal-containing conductive material so as to adjust a proper work function of the gate electrode structure with respect to the overall transistor characteristics. Moreover, if desired, a highly conductive electrode metal may be applied, for instance at a very late manufacturing stage, thereby even further enhancing electrical performance of the resulting high-k metal gate electrode structures. Although using a high-k dielectric material in combination with a highly conductive electrode material, at least provided directly on the gate dielectric material, significantly contributes to superior transistor characteristics, for instance in terms of controllability of the channel region, the ongoing shrinkage of critical dimensions, i.e., of the gate length of the transistors, driven by the demand for increasing packing density in complex semiconductor devices, may nevertheless require additional very complex measures for providing appropriate dopant profiles in the drain and source areas to achieve the desired transistor behavior. That is, upon reducing the gate length and thus the channel length of planar transistors to approximately 45 nm and less in an attempt to increase packing density in device areas requiring closely spaced transistor elements, channel controllability is still a great issue, even if using sophisticated high-k metal gate electrode structures. Consequently, although using sophisticated dielectric materials a reduced layer thickness, for instance in the range of 1.5 to several nms, has to be provided for the high-k dielectric material, possibly in combination with a thin conventional material, in order to achieve, in combination with complex drain and source dopant profiles, the required transistor controllability, which, however, may result in moderately high leakage currents. Consequently, upon further increasing the overall packing density of complex semiconductor devices, reduced transistor control and increased leakage currents, in particular in high speed signal parts of complex integrated circuits, may result in a non-acceptable overall performance.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides semiconductor devices and manufacturing techniques in which the channel length of gate electrode structures may be increased, however, without increasing the lateral dimensions of the gate electrode structures, thereby enhancing channel controllability, compared to conventional gate electrode structures having a gate length corresponding to the critical lateral design dimensions. To this end, at least a portion of the gate electrode structure may be provided as a buried electrode structure, in which the active region of the transistor may receive a recess, in which a gate dielectric material may be formed on any inner sidewall areas on the basis of well-established highly conformal deposition techniques, such as atomic layer deposition (ALD) and the like. Furthermore, an appropriate electrode material, such as a metal-containing material, possibly in combination with a semiconductor material or an electrode metal, may be provided within the recess, thereby generating a three-dimensional channel region, since any interfaces of the buried gate electrode structure may be used for establishing a conductive channel. In this manner, the lateral dimension of the gate electrode structure in the transistor length direction may be appropriately adapted to the device requirements in terms of achieving a high packing density, while, on the other hand, the actual channel length may be selected on the basis of the characteristics of the recess so as to obtain superior channel controllability and reduced leakage currents. For example, by appropriately adjusting the depth of the recess, the overall channel length may be adjusted for a given width of the recess, while a portion of the resulting channel region, which corresponds to the conventional planar channel region, may also be provided on the basis of a desired thin semiconductor material, thereby enabling a fully depleted transistor state of corresponding channel portion, which may thus further contribute to reduced leakage currents.

One illustrative method disclosed herein comprises forming a recess in a semiconductor region of a semiconductor device. The method further comprises coating inner sidewall surface areas of the recess with a dielectric material layer that comprises a high-k dielectric material. The method further comprises forming a gate electrode structure in the recess by forming an electrode material on the dielectric material layer. Additionally, the method comprises forming drain and source regions in the semiconductor region adjacent to the gate electrode structure.

A further illustrative method disclosed herein relates to forming a transistor of a semiconductor device. The method comprises forming a gate dielectric material on sidewalls and a bottom of a recess that is formed in a semiconductor region, wherein the recess extends to a first depth in the semiconductor region. The method further comprises providing an electrode material in the recess and forming drain and source regions in the semiconductor region, wherein the drain and source regions extend to a second depth that is less than the first depth.

One illustrative semiconductor device disclosed herein comprises a gate electrode structure that is laterally embedded in a semiconductor region and that extends to a first depth in the semiconductor region. The semiconductor device further comprises drain and source regions formed in the semiconductor region and extending to a second depth in the semiconductor region, wherein the second depth is less than the first depth.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1i schematically illustrate cross-sectional views of a semiconductor device during various manufacturing stages in forming a transistor element having a buried gate electrode structure, wherein the gate electrode structure may be provided prior to forming drain and source regions, according to illustrative embodiments;

FIGS. 2a-2d schematically illustrate cross-sectional views of the semiconductor device according to further illustrative embodiments, in which drain and source regions may be provided prior to forming the gate electrode structure by using a self-aligned process strategy; and

FIGS. 2e-2h schematically illustrate cross-sectional views of the semiconductor device during various manufacturing stages, wherein a dummy gate electrode structure may be provided and may be replaced by a buried gate electrode structure in an advanced manufacturing stage, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides manufacturing techniques and semiconductor devices in which superior channel control and reduced leakage currents may be accomplished in sophisticated transistor elements, wherein, at the same time, reduced lateral dimensions may be applied so as to obtain a high packing density in sophisticated semiconductor devices. For this purpose, the dimensions of gate electrode structures in a direction perpendicular to the transistor width direction, wherein this direction may still be referred to as “length direction,” may be decoupled from the actual channel length by using a buried gate electrode structure, or at least a portion of a buried gate electrode structure, so that, a horizontal channel region corresponding to the channel region of a conventional planar transistor architecture may be combined with additional non-planar regions, such as vertical channel regions, wherein the effective channel length may thus be determined on the basis of the size and shape of a corresponding recess formed in the active region of the transistor under consideration. For example, for a substantially rectangular shape of a recess, the total channel length may be adjusted for a given width of the recess along the transistor length direction by selecting an appropriate depth. The inner surface areas of the recess may then be covered or coated with an appropriate gate dielectric material, such as conventional dielectric materials in the form of silicon dioxide, silicon oxynitride and the like, possibly in combination with any high-k dielectric materials, such as hafnium oxide based materials and the like. To this end, a plurality of well-controllable process techniques have been developed in conventional process strategies and may thus be available for forming the gate dielectric material in a highly conformal manner within the recess provided in the active region. For example, as previously discussed, a plurality of process strategies have been developed for forming high-k metal gate electrode structures, wherein, in so-called replacement gate approaches, a placeholder gate electrode structure, for instance formed on the basis of polysilicon, may be laterally embedded in a dielectric material, wherein the placeholder material may then be selectively removed so as to form an opening to the active region or any etch stop material formed thereon. Thereafter, desired dielectric materials, such as high-k dielectric materials, may be applied with a high degree of controllability by applying appropriate deposition techniques, such as ALD and the like, which may represent a chemical vapor deposition (CVD) technique having a substantially self-limiting deposition behavior. That is, in corresponding CVD processes, a first precursor layer may be formed on an exposed surface area, wherein additional deposition of the first precursor material may be substantially discontinued when the exposure surface has been satisfied by the first precursor material. Thereafter, a further deposition cycle may be performed on the basis of a second precursor material, which in turn may also exhibit a self-limiting deposition behavior, thereby finally providing a desired material composition having well-controlled thickness. Upon repeating one or more deposition cycles, the finally desired layer thickness may be controlled. Consequently, the material composition and the layer thickness may be highly uniform at any exposed surface area. Moreover, additionally, sophisticated deposition techniques are available for forming appropriate metal-containing electrode materials, such as titanium nitride, tantalum nitride, aluminum and the like, so that a desired electrode material may be provided within a recess in a highly uniform manner. Consequently, by providing a recess in the active region and appropriately forming a gate dielectric material and an electrode material in the recess, in addition to the bottom face of the recess, the sidewall faces may also act as appropriate interfaces for defining a channel region in the surrounding active transistor area. For example, for a substantially rectangular cross-sectional shape of the recess, in addition to the conventional “horizontal” channel region, two additional “vertical” channel regions may be provided, thereby efficiently increasing the effective channel length, while the horizontal channel region substantially determines the lateral dimension of the gate electrode structure in the “length” direction of the transistor. Consequently, the critical dimension may be selected in view of contact requirements, i.e., in view of providing a desired low pitch between adjacent gate electrode structures in densely packed device regions, however, without unduly affecting channel control and leakage currents. In this manner, the critical dimensions and thus the packing density may be efficiently decoupled from the electronic characteristics of the transistors, which, in conventional planar transistor configurations, may result in reduced transistor performance for a gate length of 45 nm and less, as discussed above.

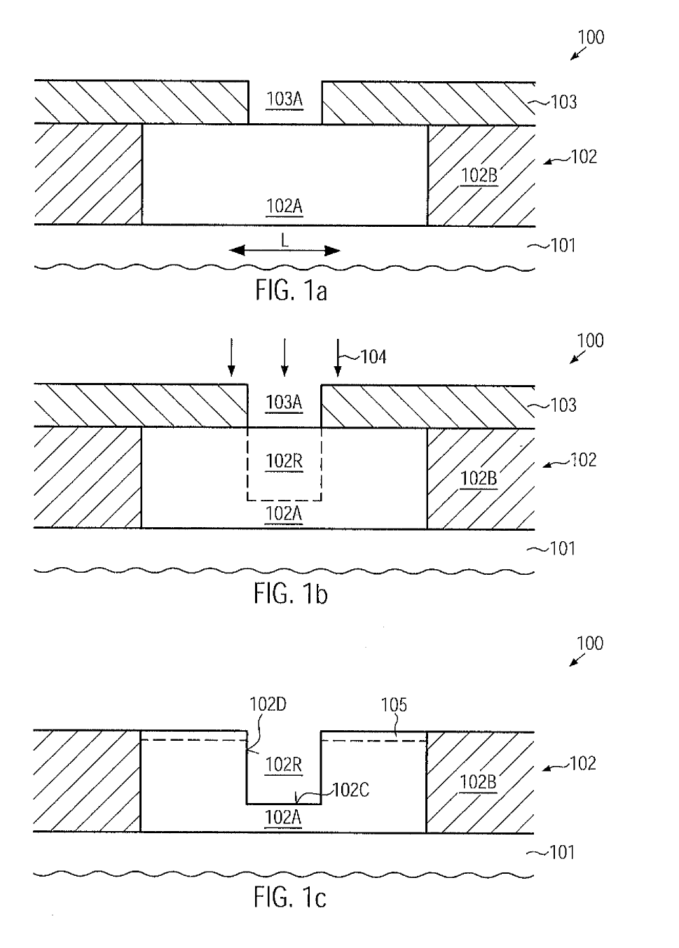

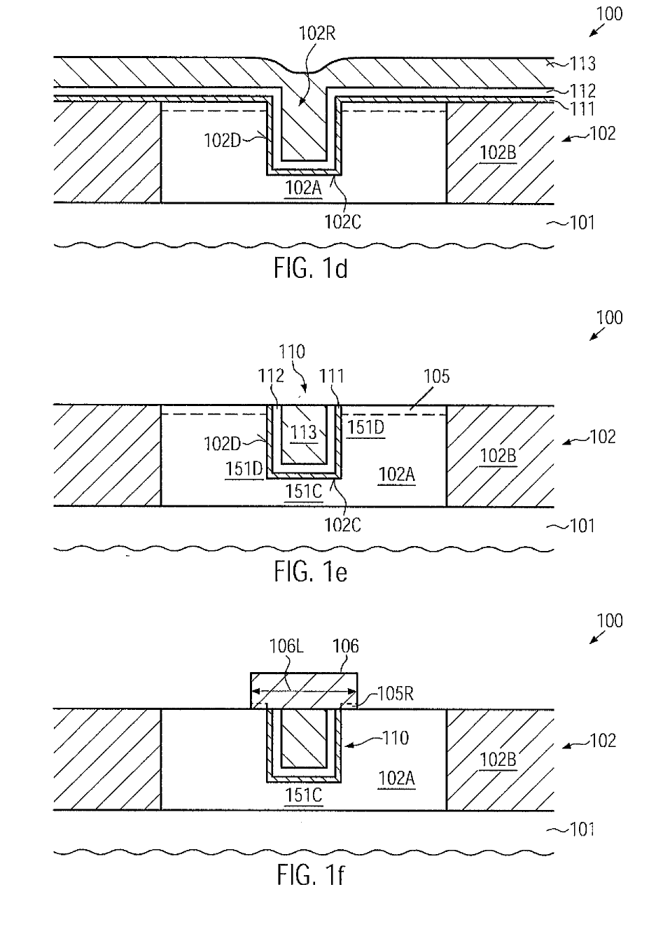

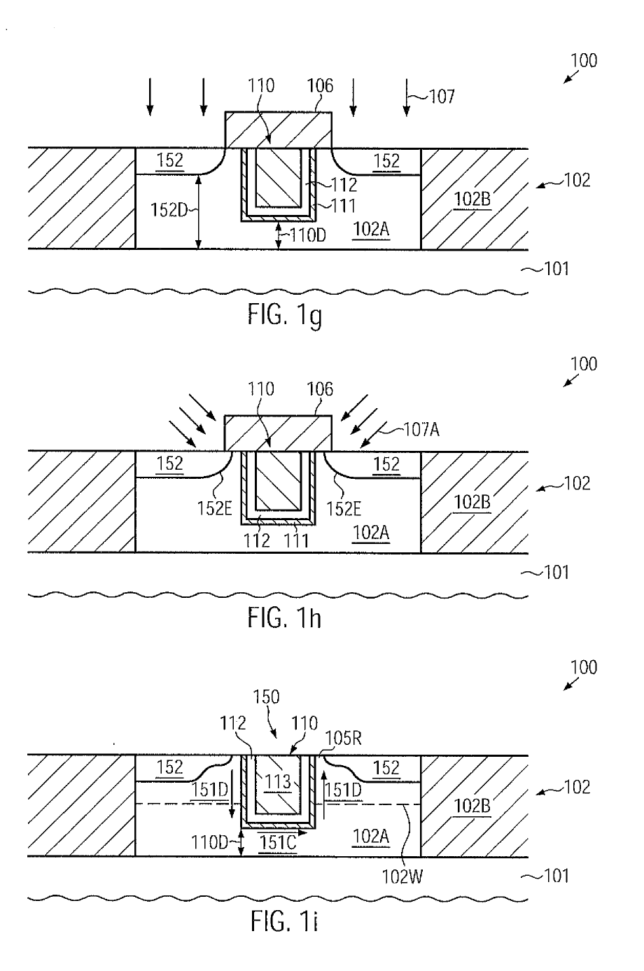

FIG. 1a schematically illustrates a cross-sectional view of a semiconductor device 100 comprising a substrate 101 and a semiconductor layer 102 that is formed above the substrate 101. The substrate 101 may represent any appropriate carrier material, such as a semiconductor material, an insulating material and the like. Similarly, the semiconductor layer 102 may initially represent any appropriate semiconductor material, such as a silicon material, a silicon/germanium material, a germanium material or any other semiconductor compound that is appropriate for forming therein and thereabove sophisticated transistor elements. Furthermore, in some illustrative embodiments, the substrate 101 in combination with the semiconductor layer 102 may represent a bulk configuration, in which the semiconductor layer 102 may be formed on a crystalline semiconductor material of the substrate 101 or the semiconductor layer 102 may represent a portion of a crystalline semiconductor material of the substrate 101. In other illustrative embodiments, the substrate 101 and the semiconductor layer 102 may represent a silicon-on-insulator (SOI) configuration, in which a buried insulating layer (not shown) may be provided below the semiconductor layer 102, thereby vertically isolating the semiconductor material 102. Furthermore, in the manufacturing stage shown, the semiconductor layer 102 may have formed therein isolation structures 102B, such as shallow trench isolations and the like, which may thus laterally delineate corresponding semiconductor regions or active regions, such as an active region 102A. In this respect, an active region is to be understood as a semiconductor region in which a PN junction of at least one transistor is to be formed or is formed. Moreover, depending on the overall process strategy, the active region 102A may have incorporated therein any appropriate dopant species, which may also be referred to as a well dopant species, in order to adjust the basic transistor characteristics. It should be appreciated, however, that any well dopant species may be, at least partially, incorporated in a later manufacturing stage, if considered appropriate. Furthermore, the dopant concentration and profile in the active region 102A may be appropriately adapted to the configuration of the transistor still to be formed therein, for instance by providing a moderately high basic dopant concentration and the like, in order to take into consideration the three-dimensional arrangement of channel regions obtained on the basis of a buried gate electrode structure still to be formed in the active region 102A. The active region 102A may have any appropriate dimension along a transistor length direction, indicated as L, so as to comply with requirements in terms of high packing density and the like, as is previously discussed. Similarly, in a transistor width direction, i.e., a direction perpendicular to the drawing plane of FIG. 1a, appropriate dimensions may be selected which may, in combination with the overall conductivity of the three-dimensional channel region still to be formed, determine the drive current capability of a corresponding transistor element. Moreover, the semiconductor device 100 may comprise an etch mask 103, which may include any appropriate material, such as a resist material, hard mask materials, anti-reflective coating (ARC) materials and the like. The etch mask 103 may comprise a mask opening 103A, which determines the lateral position and size of a recess to be formed in the active region 102A and thus the lateral size and position of a buried gate electrode structure to be provided in the active region 102A. For instance, the mask opening 103A may have a critical lateral dimension along the length direction L of 45 nm and less, if extremely scaled semiconductor devices are considered.

The semiconductor device 100 as illustrated in FIG. 1a may be formed on the basis of the following processes. Prior to or after forming the isolation structures 102B, which may be accomplished by using well-established lithography, patterning, deposition and planarization techniques, a desired dopant species may be incorporated into the active region 102A in accordance with transistor characteristics. For this purpose, well-established masking regimes are available and may be used for incorporating dopant species, for instance by ion implantation and the like. It should be appreciated that, if required, additional sacrificial materials, such as etch stop materials in the form of silicon dioxide, silicon nitride and the like, may be provided above the active region 102A prior to or after performing corresponding implantation processes. For convenience, any such optional sacrificial material layers are not shown in FIG. 1a. Next, the mask material for the mask 103 may be applied, for instance by any appropriate deposition technique, if hard mask materials and/or any other sacrificial materials may be required for obtaining the mask opening 103A having the desired critical dimensions. In other cases, the mask 103 may be provided as a resist material, if the etch resistivity thereof is sufficient for appropriately withstanding a subsequent etch process.

FIG. 1b schematically illustrates the semiconductor device 100 when exposed to a reactive etch ambient 104, which may be established on the basis of appropriate plasma-assisted etch recipes, wherein a plurality of etch chemistries are available for etching a plurality of semiconductor materials, such as silicon and the like, selectively with respect to the etch mask 103. Thus, during the etch process 104, it may be etched through any optional material layers (not shown), such as silicon dioxide and the like, and it may be etched finally into the active region 102A, as indicated by the dashed line, in order to form a recess 102R therein. In the embodiment shown in FIG. 1b, a substantially anisotropic etch behavior may be applied upon appropriately selecting the process parameters of the process 104, thereby significantly reducing any lateral etch rate upon etching material of the active region 102A. In this case, the lateral dimensions of the mask opening 103A may be transferred into the active region 102A with high fidelity. In other cases, the shape of the recess 102R may be controlled upon selecting the degree of isotropic and anisotropic etch behavior during the process 104 in order to form inclined sidewall surface areas, which may thus provide an additional degree of freedom in selecting the overall final channel length of a gate electrode structure to be formed on the basis of the recess 102R. In other cases, crystallographically anisotropic etch techniques, for instance based on potassium hydroxide and the like, may be applied so as to obtain a “sigma shaped” recess (not shown), if desired. Consequently, a plurality of well-established etch techniques may be applied, such as anisotropic process techniques, as are also used for forming isolation trenches for the structure 102B and the like, in order to appropriately adjust the cross-sectional shape of the recess 102R in accordance with overall process and device requirements. For example, for a highly anisotropic etch behavior, the final channel length may be efficiently adjusted by controlling the depth of the recess 102R.

FIG. 1c schematically illustrates the semiconductor device 100 in a further advanced manufacturing stage, in which the recess 102R may be formed in the active region 102A so as to have a bottom face 102C and sidewall faces 102D. Furthermore, as previously discussed, any appropriate dielectric material, such as silicon dioxide, silicon nitride and the like, as indicated by 105, may be formed on or above the active region 102A, if required. The device 100 as shown in FIG. 1c may be formed by removing the etch mask 103 (FIG. 1b) on the basis of any appropriate process technique, such as oxygen plasma-assisted processes, wet chemical etch processes and the like.

FIG. 1d schematically illustrates the semiconductor device 100 in a further advanced manufacturing stage. As illustrated, a stack of layers 111, 112 and 113 may be formed above the active region 102A and within the recess 102R. The layer 111 may be provided in the form of any appropriate dielectric material, which may act as a gate dielectric material. To this end, the dielectric layer 111 may comprise a conventional dielectric material, such as silicon dioxide, silicon oxynitride and the like, with a desired thickness, for instance, in the range of 0.8-1.5 nm. In other illustrative embodiments, the dielectric layer 111 may comprise a high-k dielectric material, possibly in combination with a thin conventional dielectric material, thereby providing a total thickness and material composition of the layer 111 so as to provide high capacitive coupling and reduced leakage. For example, as previously discussed, hafnium oxide based materials, zirconium oxide based materials and the like may be used as high-k dielectric materials. As previously discussed, the dielectric material 111 may be provided on the basis of any treatments and/or deposition techniques which may provide a high degree of thickness uniformity within the recess 102R so that substantially the same layer thickness may be achieved on the sidewall surface areas 102D and the bottom face 102C.

The material layer 112 may be provided in the form of a metal-containing conductive material, which may, if required, additionally comprise any metal species for appropriately adapting the work function of the material in order to appropriately adjust the threshold voltage of a transistor still to be formed in the active region 102A. For example, a plurality of metal-containing conductive materials, such as titanium nitride, tantalum nitride and the like, may be used, possibly in combination with additional work function adjusting species, such as lanthanum, aluminum and the like, so as to provide the desired electronic characteristics in combination with the dielectric layer 111. Moreover, the material layer 113 may represent a further electrode material and may be provided in the form of a semiconductor material, such as silicon, silicon/germanium and the like, or any other appropriate material, as long as a certain degree of temperature stability during the further processing may be ensured.

The semiconductor device 100 as illustrated in FIG. 1d may be formed on the basis of the following processes. The dielectric layer 111 may be formed, for instance, by sophisticated oxidation techniques and the like, if a conventional oxide-based dielectric material is to be provided. In other cases, any appropriate dielectric material may be deposited by using sophisticated highly conformal deposition techniques. Moreover, as previously discussed, high-k dielectric materials may be efficiently applied on the basis of self-limiting CVD techniques, thereby achieving a very uniform thickness on the surface areas 102D, 102C. Next, the layer 112 may be formed or any other additional layer may be provided, for instance on the basis of sophisticated deposition techniques, such as sputter deposition, CVD and the like, followed by any treatments as may be required for adjusting the overall electronic characteristics of the materials 111 and 112. For example, diffusion of work function adjusting species, such as aluminum, lanthanum and the like, may be initiated towards and into at least a portion of the dielectric material 111, if desired. Thereafter, a corresponding diffusion layer may be removed, if required, and may be replaced by the material 112. In other cases, the material 112 itself may act as a work function adjusting material and may have incorporated therein any appropriate metal species as required. Next, the additional electrode material 113 may be deposited, for instance, by low pressure CVD, for depositing a silicon material and the like. In other cases, conductive materials, such as carbon, metal compounds having a desired temperature stability and the like, may be deposited.

FIG. 1e schematically illustrates the semiconductor device 100 after the removal of any excess portions of the materials 111, 112 and 113. Hence, a gate electrode structure 110 may be provided within the active region 102A and may thus represent a buried gate electrode structure comprising the interfaces 102D, 102C, which may thus in combination define a three-dimensional channel region in the active region 102A. That is, the sidewall faces 102D may define channel regions 151D, while the bottom face 102C may define a channel region 151C, which may thus correspond to the conventional “horizontal” or planar channel region of planar transistors. It should be appreciated, however, that the configuration of the channel regions 151D, 151C may be adjusted in any different manner, for instance by appropriately selecting the shape of the recess 102R (FIG. 1c), as is also previously discussed, which may be accomplished by applying appropriate etch recipes. The removal of any excess portions of the materials 111, 112 and 113 may be accomplished on the basis of etch techniques, chemical mechanical polishing (CMP) and the like. It should be appreciated that, if required, the layer 105 may act as an efficient stop layer, which may provide superior process conditions upon completely removing any conductive material from horizontal portions above the active region 102A.

FIG. 1f schematically illustrates the semiconductor device 100 with an implantation mask 106 formed above the active region 102A in order to cover the gate electrode structure 110 and also a portion of the active region 102A. That is, a length 106L of the implantation mask 106 may be selected such that drain and source regions may be formed in the active region 102A laterally offset from the gate electrode structure 110 in accordance with the overall transistor characteristics. Furthermore, if desired, the mask 106 may be used for removing an exposed portion of the layer 105 (FIG. 1e), thereby preserving residual portions 105R, if required. The implantation mask 106 may be provided in the form of a resist material or any other appropriate material having a thickness so as to provide the required ion blocking effect. To this end, any well-established lithography techniques may be applied.

FIG. 1g schematically illustrates the semiconductor device 100 during an ion implantation process 107, in which appropriate drain and source region dopant species may be incorporated into the active region 102A on the basis of the implantation mask 106. During the implantation process 107, appropriate process parameters, i.e., implantation dose and implantation energy, are selected for a given implantation species in order to obtain the desired vertical dopant profile. As illustrated, drain and source regions 152 may be formed in the active region 102A so as to extend to a specified depth 152D, which may be less than a depth 110D to which the gate electrode structure 110 extends in the active region 102A. That is, a corresponding PN junction formed by the drain and source dopant species of the region 152 with the well dopant species provided in the active region 102A may be positioned at a depth 152D that is less than the depth 110D. It should be appreciated that an appropriate concentration and depth 152D may be readily determined on the basis of simulations, experiments and the like. Thus, the transistor characteristics may be efficiently adjusted on the basis of the gate electrode structure 110, i.e., its cross-sectional shape, the depth 110D and the material characteristics of the layers 111 and 112, and on the basis of the dopant profile and concentration, as well as the lateral position of the drain and source regions 152.

FIG. 1h schematically illustrates the semiconductor device 100 according to further illustrative embodiments, in which one or more additional implantation processes 107A may be performed so as to provide a graded dopant profile for the drain and source regions 152, if required. For example, based on the implantation mask 106, a tilted implantation may be performed so as to form drain and source extension regions 152E. It should be appreciated that other implantation species may also be incorporated, such as additional well dopant species and the like, if required.

FIG. 1i schematically illustrates the semiconductor device 100 in a further advanced manufacturing stage. As illustrated, a transistor 150 may be formed on the basis of the gate electrode structure 110 and the drain and source regions 152, which may have any appropriate lateral and vertical dopant profile, as discussed above, which may receive its final profile on the basis of anneal techniques in order to activate the dopants and re-crystallize implantation-induced damage. Consequently, the transistor 150 may comprise the channel region 151D, which may thus represent non-planar channel regions and comprise the channel region 151C, which may represent a substantially horizontal channel region, if the gate electrode structure 110 may be provided in a substantially rectangular shape, if viewed in cross-section as shown in FIG. 1i. As previously indicated, the combined channel regions 151D, 151C may also have any other appropriate three-dimensional shape, depending on the previous process strategy for forming the cavity 102R (FIG. 1b). Thus, based on appropriate well doping 102W within the active region 102A, a controlled charge carrier flow may be initiated in the channel regions 151D, 151C, as indicated by the arrows, wherein, due to the increased overall length of the resulting three-dimensional channel, superior control and thus reduced leakage currents may be achieved. Moreover, by appropriately selecting the depth 110D, the height of the channel region 151C may be selected and may thus provide the possibility of reducing the corresponding semiconductor thickness, such that the channel region 151C may represent a fully depleted region, thereby even further reducing any off-currents of the transistor 150.

Based on the basic configuration of the transistor 150, the processing may be continued, for instance, by forming appropriate contact areas in the drain and source regions 152, if required, for instance by providing a metal silicide, wherein a metal silicide may also be formed in the gate electrode structure 110, if the material 113 may comprise a silicon species. For this purpose, well-established silicidation techniques may be applied, wherein the residuals 105R, if provided, may provide superior process conditions, for instance in terms of reducing leakage paths between the gate electrode structure 110 and the drain and source regions 152. Furthermore, a superior contact process may result from the superior topography of the transistor 150 due to the presence of the buried gate electrode structure 110, since, after providing any interlayer dielectric material, corresponding contact holes may extend to substantially the same level for the drain and source regions 152 and the gate electrode structure 110, thereby enhancing process uniformity and thus performance of the resulting contact elements.

It should be appreciated that further performance increasing mechanisms may be implemented in the transistor 150, for instance by providing the material 112 and/or a portion of the material 113 in the form of a highly stressed material, for instance having a high internal compressive stress, which may thus result in a corresponding strain component in the channel regions 151D, 151C, thereby increasing charge carrier mobility of P-channel transistors.

Furthermore, the transistor 150 may be formed on the basis of a process strategy in which the drain and source regions 152 may be provided prior to forming the gate electrode structure 110, so that exposure of the gate electrode structure 110 to any high temperature processes may be avoided. In this case, highly conductive materials, such as aluminum, copper, tungsten and the like, may be used. To this end, an implantation mask may be provided prior to forming a recess in the active region 102A so as to form the drain and source regions 152, followed by any anneal processes, as required, after removing the implantation mask. Thereafter, an etch mask, for instance as previously described, may be provided so as to form a recess and filling the recess with appropriate materials, thereby providing the gate electrode structure 110.

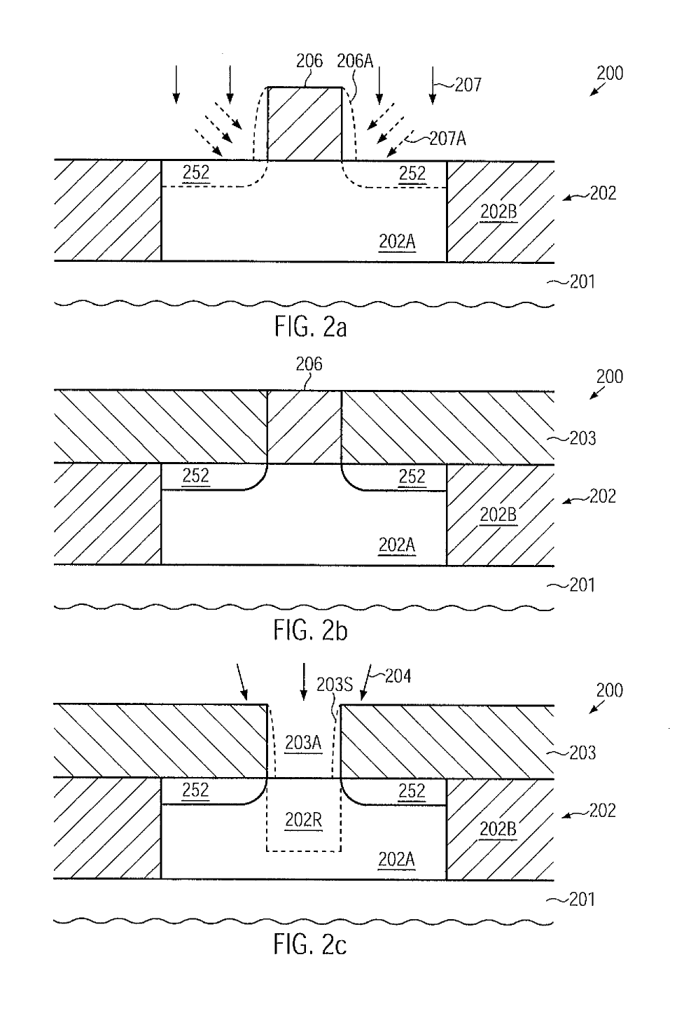

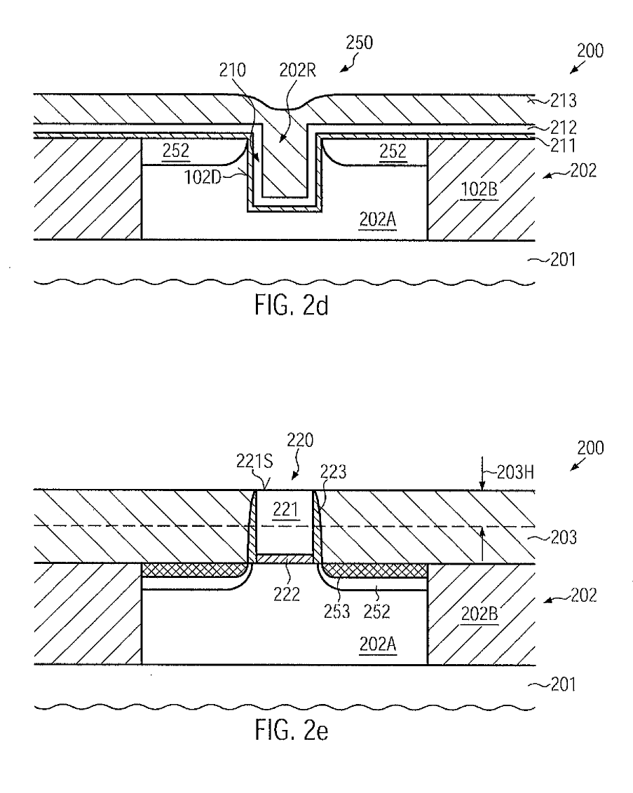

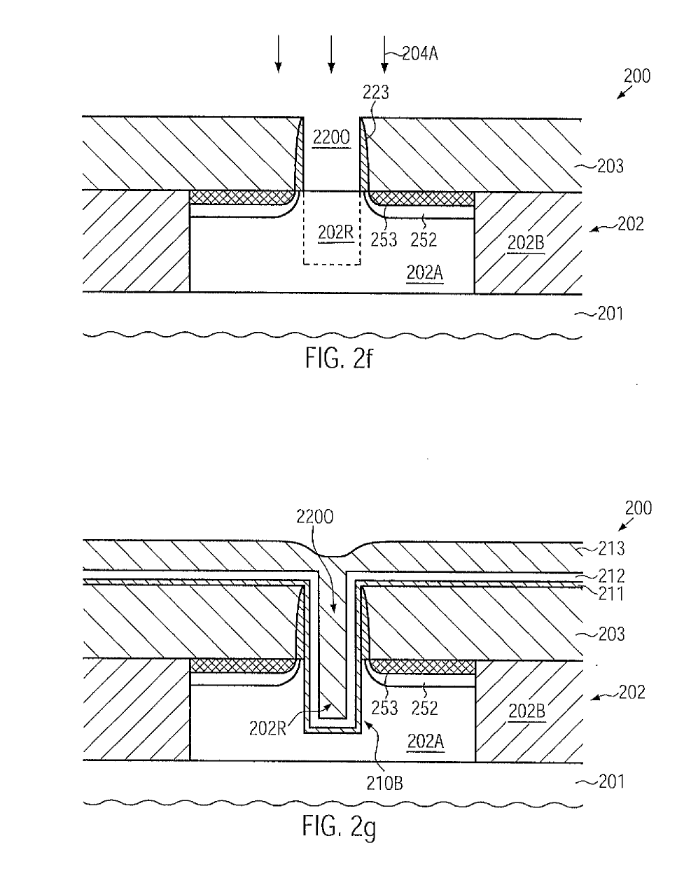

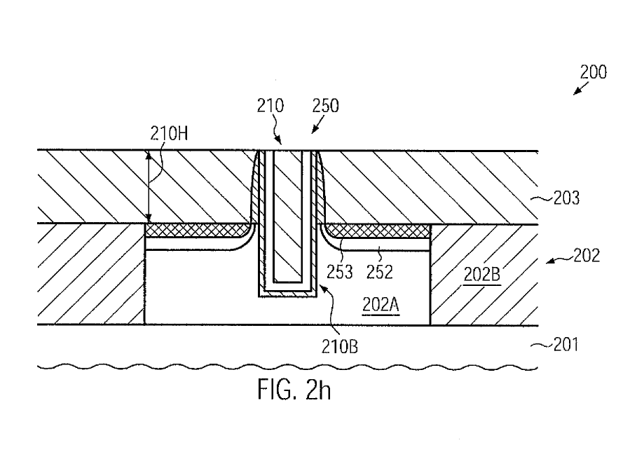

With reference to FIGS. 2a-2h, further illustrative embodiments will now be described, in which the buried gate electrode structure may be formed in a late manufacturing stage, i.e., after forming the drain and source regions, while nevertheless providing a self-aligned positioning of the gate electrode structure with respect to the drain and source regions.

FIG. 2a schematically illustrates a cross-sectional view of a semiconductor device 200 comprising a substrate 201 and a semiconductor layer 202 formed above the substrate 201. An active region 202A may be formed in the semiconductor layer 202 and may be delineated by trench isolation structures 202B. With respect to these components, the same criteria may apply as previously discussed with reference to the semiconductor device 100. Moreover, in the manufacturing stage shown, an implantation mask 206, such as well-established hard mask materials, resist materials and the like, may be provided so as to determine the lateral offset of drain and source regions 252 to be formed in the active region 202A on the basis of appropriate implantation processes 207, possibly in combination with tilted implantation techniques 207A. The implantation mask 206 may be provided on the basis of any appropriate deposition technique, for instance for providing appropriate hard mask materials, such as silicon dioxide, silicon nitride, carbon material and the like, and patterning the same on the basis of lithography techniques. In other cases, the mask 206 may be provided in the form of a resist material or any other organic polymer material, if desired. In some illustrative embodiments, additional sidewall spacer elements 206A may be provided, when a pronounced graded lateral dopant profile for the regions 252 may be required. In other cases, as previously discussed, a tilted implantation process, such as the process 207A, may be applied so as to obtain the desired dopant profile.

FIG. 2b schematically illustrates the semiconductor device 200 in a further advanced manufacturing stage. As illustrated, a mask material 203 may be provided so as to laterally enclose the implantation mask 206. To this end, any appropriate material, such as organic planarization materials, conventional dielectric materials and the like, may be used as long as the mask material 203 may have a different etch behavior compared to the implantation mask 206. For example, material may be deposited on the basis of CVD techniques and the like and any excess material may be removed so as to expose the implantation mask 206. Thereafter, an appropriate etch process may be applied, for instance a wet chemical etch process, plasma-assisted etch processes, in which the material of the implantation mask 206 may be removed selectively with respect to the mask material 203. For this purpose, a plurality of well-established plasma-assisted or wet chemical etch recipes are available. It should be appreciated that the active region 202A or at least a portion thereof may still have formed thereon any appropriate dielectric material, as is, for instance, also discussed above with reference to the optional layer 105 for the semiconductor device 100 (for instance, FIG. 1c).

FIG. 2c schematically illustrates the semiconductor device 200 in a further advanced manufacturing stage. As shown, an etch process 204 may be performed so as to provide a recess 202R in the active region 202A, wherein the lateral size and position of the recess 202R is determined on the basis of an opening 203A that is formed upon removing the implantation mask 206 (FIG. 2b). With respect to any process parameters and characteristics of the etch process 204, it may be referred to the process strategy previously explained with reference to the device 100. That is, the size and shape, i.e., the depth and the cross-sectional shape, of the recess 202R may be adjusted on the basis of appropriately selecting the parameters of the process 204. Moreover, depending on the previous process strategy in providing the drain and source regions 252, spacer elements 203S may be provided within the opening 203A in order to reduce the critical dimension of the recess 202R, thereby obtaining lateral offset from the drain and source regions 252, if required. To this end, appropriate material may be deposited after the removal of the implantation mask 206 (FIG. 2b), thereby reducing the width of the opening 203A as desired. After the etch process 204, the mask material 203 may be removed selectively with respect to the active region 202A, which may be accomplished by applying any appropriate etch recipe.

FIG. 2d schematically illustrates the semiconductor device 200 with a plurality of gate materials 211, 212, 213 formed above the active region 202A and within the recess 202R. It should be appreciated that a superior degree of freedom in selecting appropriate materials may be provided due to the fact that any high temperature processes may not be required, since the drain and source regions 252 already have the final doping profile. For example, the material 211 may be provided as a highly conformal dielectric layer, possibly including a high-k dielectric material, as previously discussed. Furthermore, the layer 212 may be provided as a metal-containing cap material, possibly including an appropriate work function adjusting species, followed by the further electrode material 213, for instance in the form of aluminum and the like. Next, any excess portions of the materials 211,212 and 213 may be removed by any appropriate process technique, thereby providing a buried gate electrode structure 210 of a transistor 250, similarly as is previously discussed with reference to the device 100. Consequently, the gate electrode structure 210 may be provided in a self-aligned manner with respect to the drain and source regions 252, while at the same time avoiding exposure to any high temperature processes upon forming the gate electrode structure 210. It should be appreciated that the drain and source regions 252 may also have formed therein metal silicide regions, which may be accomplished by performing a silicidation process prior to forming the gate electrode structure 210.

With reference to FIGS. 2e-2h, further illustrative embodiments will now be described so as to provide a self-aligned buried gate electrode structure in a late manufacturing stage.

FIG. 2e schematically illustrates the device 200 in a manufacturing stage in which the drain and source regions 252 may be provided in the active region 202A, possibly in combination with metal silicide regions 253. Furthermore, a placeholder or dummy gate electrode structure 220 may be formed above the active region 202A and may comprise, for instance, placeholder material 221, such as a polysilicon material and the like, in combination with a gate dielectric layer 222, such as a silicon dioxide material and the like. Furthermore, a sidewall spacer structure 223 may be provided in the placeholder gate electrode structure 220. Furthermore, the mask material 203, which may represent a portion of an interlayer dielectric material, may be provided so as to laterally enclose the placeholder gate electrode structure 220.

The semiconductor device 200 as illustrated in FIG. 2e may be formed on the basis of any appropriate process strategy, in which the gate electrode structure 220 may be patterned in accordance with well-established process strategies, followed by the formation of the drain and source regions 252, using the gate electrode structure 220 as an efficient implantation mask. After any high temperature processes, the metal silicide regions 253, if required, may be formed, followed by the deposition of the mask material 203, for instance in the form of silicon nitride, silicon dioxide and the like. Next, the material 203 may be planarized, for instance by CMP, thereby also exposing a top surface 221S of the placeholder material 221. It should be appreciated that a desired reduction in height of the mask material 203, as indicated by 203H, may be applied in this manufacturing stage, for instance for reducing the aspect ratio of an opening still to be formed during the further processing, when providing the gate materials for the buried gate electrode structure. Next, material 221 may be removed on the basis of any appropriate etch chemistry, such as wet chemical etch recipes, plasma-assisted etch recipes and the like, wherein the material 222 may act as an etch stop material for enhancing overall process control.

FIG. 2f schematically illustrates the semiconductor device 200 during an etch process 204A, in which a gate opening 2200, obtained by removing the materials 221 and 222 of the gate electrode structure 220 (FIG. 2e), may act as a mask opening of the material 203, in combination with the spacer elements 223. It should be appreciated that if the spacer elements 223 are not provided, corresponding spacer elements may be formed within the opening 2200 so as to define a length of a recess 202R to be formed in the active region 202A on the basis of the etch process 204A. With respect to any process parameters of the process 204A and thus of the depth and cross-sectional shape of the recess 202R, it may be referred to the embodiments described above.

FIG. 2g schematically illustrates the semiconductor device 200 in a further advanced manufacturing stage, in which the gate materials 211, 212 and 213 may be provided within the recess 202R and thus within the opening 2200. To this end, any of the above-described deposition techniques may be applied, wherein, as discussed above, the resulting aspect ratio of the combined opening 220O, 202R may be adjusted by appropriately reducing the thickness of the mask material 203. Consequently, upon filing the recess 202R, a buried portion 210B of a gate electrode structure may be provided within the active region 202A in a self-aligned manner with respect to the drain and source regions 252.

FIG. 2h schematically illustrates the semiconductor device 200 after the removal of any excess material. Hence, a transistor 250 may comprise a gate electrode structure 210 having the buried portion 210B, which may provide the three-dimensional channel regions, as previously discussed, within the active region 202A. It should be appreciated that, upon removing any excess material of the gate electrode structure 210, a desired final height level 210H may be adjusted for the gate electrode structure 210 by continuing the removal process.

Consequently, the gate electrode structure 210 may be provided with superior characteristics in terms of channel length and thus channel control and leakage currents by providing the buried portion 210B, while nevertheless providing a high degree of compatibility with conventional replacement gate approaches. It should be appreciated that the buried portion 210B may be provided locally for some transistors, while other transistors may be formed on the basis of a conventional planar transistor architecture, which may be accomplished by providing appropriate dopant profiles selectively for these transistors and avoiding the formation of a recess in the corresponding active regions.

As a result, the present disclosure provides manufacturing techniques and semiconductor devices in which a buried gate electrode structure may provide superior channel controllability at reduced leakage currents, while nevertheless allowing reduced critical dimensions and thus enhanced packing densities in sophisticated semiconductor devices.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a recess in a semiconductor region of a semiconductor device;
coating inner sidewall surface areas of said recess with a dielectric material layer that comprises a high-k dielectric material;
forming a gate electrode structure in said recess by forming an electrode material on said dielectric material layer; and
forming drain and source regions in said semiconductor region adjacent to said gate electrode structure.

2. The method of claim 1, wherein forming an electrode material on said dielectric material layer comprises forming a metal-containing conductive material layer on said dielectric material layer.

3. The method of claim 2, wherein forming an electrode material on said dielectric material layer further comprises forming a conductive material on said metal-containing conductive material layer.

4. The method of claim 1, wherein said drain and source regions are formed after forming said gate electrode structure.

5. The method of claim 1, wherein said drain and source regions are formed prior to forming said recess.

6. The method of claim 5, wherein forming said drain and source regions comprises providing an implantation mask above said semiconductor region and implanting drain and source dopants by using said implantation mask.

7. The method of claim 6, further comprising forming a mask material laterally around said implantation mask, removing said implantation mask selectively to said mask material so as to form a mask opening and forming said recess by using said mask opening.

8. The method of claim 7, further comprising removing said mask material.

9. The method of claim 7, further comprising preserving at least a portion of said mask material as an interlayer dielectric material of said semiconductor device.

10. The method of claim 1, wherein forming said electrode material in said recess comprises forming a semiconductor material in said recess.

11. A method of forming a transistor of a semiconductor device, the method comprising:
forming a gate dielectric material on sidewalls and a bottom of a recess formed in a semiconductor region, said recess extending to a first depth in said semiconductor region;
providing an electrode material in said recess; and
forming drain and source regions in said semiconductor region, said drain and source regions extending to a second depth that is less than said first depth.

12. The method of claim 11, wherein forming a gate dielectric material comprises depositing at least one layer including a high-k dielectric material.

13. The method of claim 11, wherein providing an electrode material in said recess comprises forming a metal-containing conductive material on said gate dielectric material.

14. The method of claim 11, wherein said drain and source regions are formed prior to forming said recess.

15. The method of claim 14, wherein forming said drain and source regions comprises providing a mask and using said mask as an implantation mask and for forming an etch mask so as to form said recess.

16. The method of claim 11, wherein providing an electrode material in said recess comprises replacing a placeholder material formed in said recess by a metal-containing material.

17. A semiconductor device, comprising:
a gate electrode structure laterally embedded in a semiconductor region, said gate electrode structure extending to a first depth in said semiconductor region; and
drain and source regions formed in said semiconductor region and extending to a second depth in said semiconductor region, said second depth being less than said first depth.

18. The semiconductor device of claim 17, wherein said gate electrode structure comprises a gate dielectric layer formed at sidewalls and a bottom of said gate electrode structure, wherein said gate dielectric layer comprises a high-k dielectric material.

19. The semiconductor device of claim 18, wherein said gate electrode structure comprises a metal-containing electrode material that is formed on said gate dielectric layer.

20. The semiconductor device of claim 17, wherein a length of said gate electrode structure at a bottom thereof is 45 nm or less.
